(19) United States
(12) Patent Application Publication
(10) Pub. No.: US 2025/0240941 A1
(43) Pub. Date: Jul. 24, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Wei Xu, Wuhan (CN); Zongliang Huo, Wuhan (CN)

(21) Appl. No.: 18/435,736

(22) Filed: Feb. 7, 2024

Related U.S. Application Data
(63) Continuation of application No. PCT/CN2024/073813, filed on Jan. 24, 2024.

(51) Int. Cl. H10B 12/00

(52) U.S. Cl. CPC H10B 12/395; H10B 12/482; H10B 12/485; H10B 12/488

(57) ABSTRACT

Three-dimensional (3D) semiconductor devices and fabricating methods are provided. In some implementations, a disclosed semiconductor device comprises an array of channel structures each vertically extending in a stack structure. The stack structure includes a first conductive layer and a second conductive layer over the first conductive layer. The semiconductor device further includes first isolation structures each extending along a first lateral direction and separating the first conductive layer into first conductive lines, and second isolation structures each extending along the first lateral direction and separating the second conductive layer into second conductive lines. Each first isolation structure is separated from the second isolation structures by at least one row of the channel structures that are aligned along the first lateral direction.

### CROSS-REFERENCE TO RELATED APPLICATIONS

This application is a continuation of International Application No. PCT/CN2024/073813, filed on Jan. 24, 2024, entitled “SEMICONDUCTOR DEVICES AND FABRICATING METHODS THEREOF,” which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

Implementations of the present disclosure provide semiconductor devices and fabricating methods thereof.

One aspect of the present disclosure provides a semiconductor device. The semiconductor device comprises an array of channel structures each vertically extending in a stack structure comprising a first conductive layer and a second conductive layer over the first conductive layer; first isolation structures each extending along a first lateral direction and separating the first conductive layer into first conductive lines; and second isolation structures each extending along the first lateral direction and separating the second conductive layer into second conductive lines, wherein each first isolation structure is separated from the second isolation structures by at least one row of the channel structures that are aligned along the first lateral direction.

In some implementations, one of the first conductive lines laterally extending along the first lateral direction and surrounds each channel structure in a first row of the array and a second row of the array adjacent to the first row; and one of the second conductive lines laterally extending along the first lateral direction and surrounds each channel structure in the second row of the array and a third row of the array adjacent to the second row.

In some implementations, the stack structure further comprises a third conductive layer on the third conductive layer; the semiconductor device further comprises third isolation structures each extending along the first lateral direction and separating the third conductive layer into third conductive lines; and each third isolation structure is separated from the first isolation structures and the second isolation structures by at least one row of the channel structures.

In some implementations, the semiconductor device further comprises one of the first conductive lines laterally extending along the first lateral direction and surrounds each channel structure in a first row of the array, a second row of the array adjacent to the first row, and a third row of the array adjacent to the second row; one of the second conductive lines laterally extending along the first lateral direction and surrounds each channel structure in the second row and the third row of the array, and a fourth row of the array adjacent to the third row; and one of the third conductive lines laterally extending along the first lateral direction and surrounds each channel structure in the third row and the fourth row of the array, and a fifth row of the array adjacent to the fourth row.

In some implementations, the semiconductor device further comprises dielectric structures each vertically extending through the stack structure and one first isolation structure or second isolation structure.

In some implementations, the semiconductor device further comprises a cross-section of each dielectric structure in a lateral plane has a round shape, an oval shape, or a short-slit shape.

In some implementations, each of the first isolation structures and the second isolation structures includes a straight dielectric wall.

In some implementations, the semiconductor device further comprises bit lines each connected with a corresponding column of channel structures and laterally extending along a second lateral direction perpendicular to the first lateral direction.

In some implementations, each of the first isolation structures and the second isolation structures has a waved dielectric wall.

In some implementations, the semiconductor device further comprises bit lines connected with the channel structures and laterally extending parallel along a second lateral direction non-perpendicular to the first lateral direction.

In some implementations, the semiconductor device further comprises first word line contacts connected with the first conductive lines, respectively; and second word line contacts connected with the second conductive lines, respectively, wherein the first word line contacts and the second word line contacts are located on a same side of the first conductive layer and the second conductive layer.

In some implementations, the semiconductor device further comprises first word line contacts connected with a first side of the first conductive lines, respectively; and second word line contacts connected with a second side of the second conductive lines, respectively, wherein the first side and the second side are opposite with each other.

In some implementations, each channel structure comprises a semiconductor core vertically extending in the stack structure; and a gate dielectric layer laterally surrounding the semiconductor core and vertically extending in the stack structure.

In some implementations, each channel structure comprises a semiconductor core vertically extending in the stack structure; a first gate dielectric layer laterally surrounding a first portion of the semiconductor core corresponding to the first conductive layer; and a second gate dielectric layer laterally surrounding a second portion of the semiconductor core corresponding to the second conductive layer, wherein the first gate dielectric layer is separated from the second gate dielectric layer by a third portion of the semiconductor core between the first portion and the second portion.

In some implementations, a first lateral size of the first portion of the semiconductor is substantially equal to a second lateral size of the second portion of the semiconductor; and a third lateral size of the third portion of the semiconductor is substantially equal to the first lateral size of the first portion of the semiconductor plus a lateral thickness of the first gate dielectric layer.

In some implementations, the semiconductor device further comprises an array of capacitors, each capacitor connected with a corresponding channel structure.

In some implementations, a cross section of each channel structure in the lateral plane is a round shape or an oval shape.

In some implementations, the first isolation structures each extending through the first conductive layer and without extending through the second conductive layer; and the second isolation structures each extending through the second conductive layer and without extending through the first conductive layer.

Another aspect of the present disclosure provides a method of forming a semiconductor device. The method comprises forming first isolation structures each extending along a first lateral direction and separating a first sacrificial layer into first sacrificial lines; forming second isolation structures each extending along the first lateral direction and separating a second sacrificial layer into second sacrificial lines, wherein a pair of adjacent first isolation structure and second isolation structure has a distance along a second lateral direction perpendicular to the first lateral direction; and forming an array of semiconductor pillars each vertically extending through the first sacrificial layer and the second sacrificial layer, wherein a row of the array of semiconductor pillars along the first lateral direction is located between the pair of adjacent first isolation structure and second isolation structure.

In some implementations, the method further comprises forming bit lines extending parallel along the second lateral direction; forming a first dielectric layer on the bit lines; forming the first sacrificial layer on the first dielectric layer; forming a second dielectric layer on the first sacrificial layer and the first isolation structures; and forming a second sacrificial layer on the second dielectric layer.

In some implementations, the method further comprises forming through holes each extending through the second sacrificial layer, the second dielectric layer, and the first sacrificial layer; removing the first sacrificial lines to form first horizontal trenches and removing the second sacrificial lines to form second horizontal trenches, the first and second horizontal trenches exposing portions of sidewalls of the semiconductor pillars; and oxidizing the exposed portions of sidewalls of the semiconductor pillars.

In some implementations, the method further comprises filling a conductive material in the first horizontal trenches to form first conductive lines, and in the second horizontal trenches to form second conductive lines; removing portions of the conductive material exposed by the through holes; and filling a dielectric material to fill the through holes to form dielectric structures.

In some implementations, the method further comprises forming first word line contacts connected with the first conductive lines; and forming second word line contacts connected with the second conductive lines, wherein the first word line contacts and the second word line contacts are formed on a same side of the first conductive lines and the second conductive lines.

In some implementations, the method further comprises forming first word line contacts connected with a first side of the first conductive lines; and forming second word line contacts connected with a second side of the second conductive lines, wherein the first side and the second side are opposite with each other.

In some implementations, the method further comprises forming capacitors each in contact with a corresponding one of the semiconductor pillars.

Another aspect of the present disclosure provides a method of forming a semiconductor device. The method comprises forming first isolation structures each extending along a first lateral direction and separating a first conductive layer into first conductive lines; forming second isolation structures each extending along the first lateral direction and separating a second conductive layer into second conductive lines, wherein a pair of adjacent first isolation structure and second isolation structure has a distance along a second lateral direction perpendicular to the first lateral direction; and forming an array of semiconductor pillars each vertically extending through the first conductive layer and the second conductive layer, wherein a row of the array of semiconductor pillars along the first lateral direction is located between the pair of adjacent first isolation structure and second isolation structure.

In some implementations, the method further comprises forming bit lines extending parallel along a second lateral direction; forming a first dielectric layer on the bit lines; forming the first conductive layer on the first dielectric layer; forming a second dielectric layer on the first conductive layer and the first isolation structures; and forming the second conductive layer on the second dielectric layer.

In some implementations, the method further comprises forming channel holes each extending through the second conductive layer, the second dielectric layer, the first conductive layer, and the first dielectric layer; forming a gate dielectric layer on sidewalls of the channel holes; and forming the array of semiconductor pillars in the channel holes.

In some implementations, the method further comprises forming first word line contacts connected with the first conductive lines; and forming second word line contacts connected with the second conductive lines, wherein the first word line contacts and the second word line contacts are formed on a same side of the first conductive lines and the second conductive lines.

In some implementations, the method further comprises forming first word line contacts connected with a first side of the first conductive lines; and forming second word line contacts connected with a second side of the second conductive lines, wherein the first side and the second side are opposite with each other.

In some implementations, the method further comprises forming capacitors each in contact with a corresponding one of the semiconductor pillars.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including vertical transistors, according to some implementations of the present disclosure.

FIG. 2A illustrates a schematic plan perspective view of a memory device, according to some implementations of the present disclosure.

FIG. 2B illustrates a schematic side view of a cross-section of a portion of the 3D memory device of FIG. 2A, according to some implementations of the present disclosure.

FIG. 2C illustrates a schematic plan view of a first layer of memory cells in the memory device of FIG. 2A, according to some implementations of the present disclosure.

FIG. 2D illustrates a schematic plan view of a second layer of memory cells in the memory device of FIG. 2A, according to some implementations of the present disclosure.

FIG. 3A illustrates a schematic plan perspective view of another memory device, according to some implementations of the present disclosure.

FIG. 3B illustrates a schematic plan perspective view of another memory device, according to some implementations of the present disclosure.

FIG. 4A illustrates a schematic plan perspective view of another memory device, according to some other implementations of the present disclosure.

FIG. 4B illustrates a schematic side view of a cross-section of a portion of the 3D memory device of FIG. 4A, according to some implementations of the present disclosure.

FIG. 5 illustrates a block diagram of a system having a memory device, according to some implementations of the present disclosure.

FIG. 6 illustrates a flowchart of a fabricating method for forming a 3D memory device, according to some implementations of the present disclosure.

FIGS. 7A-7J each illustrates a schematic side cross-sectional view of a 3D memory device at a certain fabricating stage of the method shown in FIG. 6, according to various implementations of the present disclosure.

FIG. 8 illustrates a flowchart of another fabricating method for forming a 3D memory device, according to some implementations of the present disclosure.

FIGS. 9A-9H each illustrates a schematic side cross-sectional view of a 3D memory device at a certain fabricating stage of the method shown in FIG. 5, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure, the data are stored in the capacitors. In the vertical gate DRAM process technology route, there are two architectural directions. One architectural direction is single metal gate (SMG), which saves area, but has poor gate control and high process difficulty. The other architectural direction is gate all around (GAA), which can directly or epitaxially form the channel and has better channel holes. Both existing architectural designs have a problem of difficulty in shrinking the sizes.

To address one or more of the aforementioned issues, the present disclosure introduces a solution based on the GAA architecture in which new word line structures and control methods are proposed to avoid the problem of difficulty in shrinking thereby breaking the current density limit. Consistent with the scope of the present disclosure, according to some implementations of the present disclosure, vertical GAA structure and double-layer or multi-layer word lines with staggered isolation structures are used in the disclosed memory devices. Specifically, the word line gates can be formed by using an alternative dielectric stack and a subsequent gate replacement process, and the channel structures can be formed by using epitaxial growth to realize the channel. The multi-layer word lines can be formed by using staggered isolation structures. As such, each word line has an individual current path without the danger of being cut off and without word line recess variation. Therefore, the disclosed memory devices can overcome the difficulty of shrinking the GAA to achieve high-density DRAM with better gate controlling and lower cost.

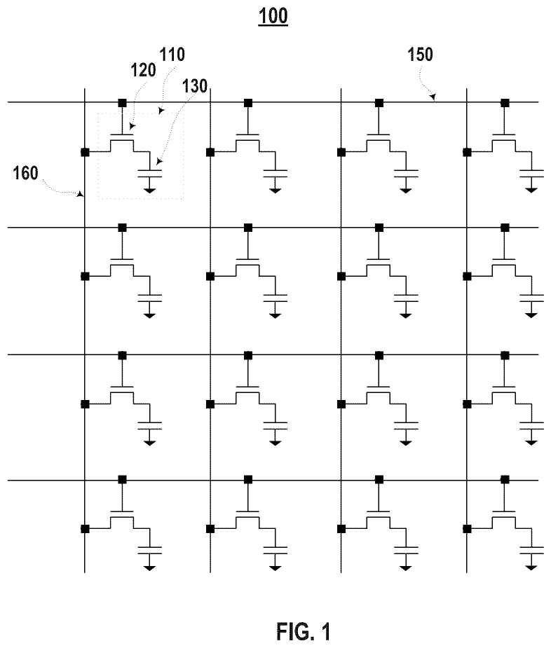

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

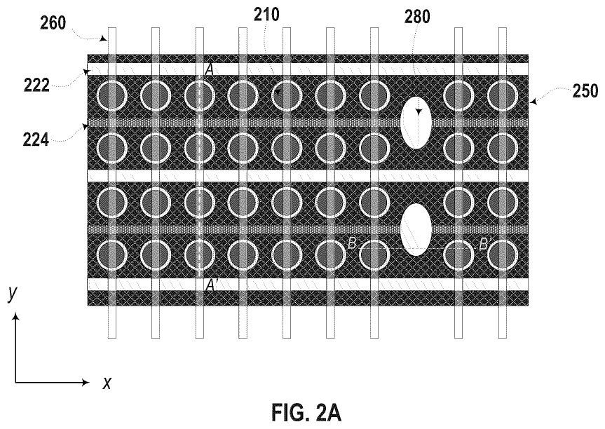

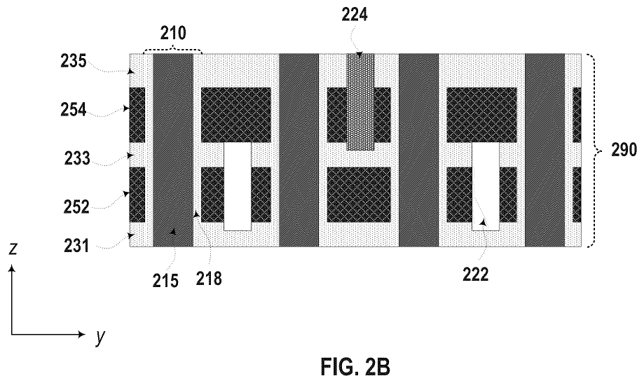

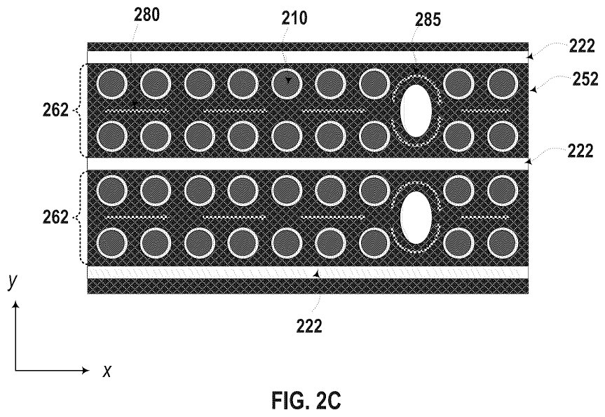

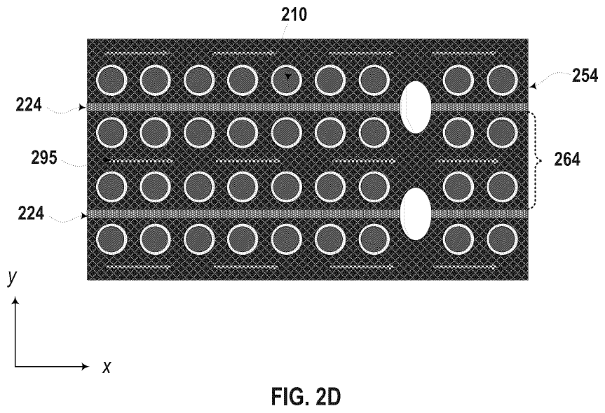

FIG. 2A illustrates a schematic plan perspective view of a memory device, according to some implementations of the present disclosure. FIG. 2B illustrates a schematic side view of a cross-section of a portion of the 3D memory device of FIG. 2A, according to some implementations of the present disclosure. FIG. 2C illustrates a schematic plan view of a first layer of memory cells in the memory device of FIG. 2A, according to some implementations of the present disclosure. FIG. 2D illustrates a schematic plan view of a second layer of memory cells in the memory device of FIG. 2A, according to some implementations of the present disclosure.

As shown in FIG. 2A, the disclosed memory device can include an array of channel structures 210 each extending along a vertical direction, a plurality of word lines 250 each extending in a first lateral direction (the x-direction, referred to as the word line direction), and a plurality of bit lines 260 each extending in a second lateral direction perpendicular to the first lateral direction (the y-direction, referred to as the bit line direction). Each bit line 260 connects to a corresponding column of vertical transistors along the second lateral direction (the y-direction). Each word line 250 is separated from its adjacent word line by first isolation structure 222 or second isolation structure 224. It is understood that FIG. 2A does not illustrate cross-section views of the memory device in the same lateral plane, and first isolation structures 222, second isolation structures 224, word lines 250 and bit lines 260 may be formed in different lateral planes for ease of routing, as described below in detail.

FIG. 2B shows a schematic side view of a cross-section of a portion of the 3D memory device of FIG. 2A along the AA′ line. In some implementations in the vertical direction (the z-direction), the disclosed memory device can include a stack structure 290 including a first dielectric layer 231, a first conductive layer 252 on the first dielectric layer 231, a second dielectric layer 233, a second conductive layer 254 on the second dielectric layer 233, and a third dielectric layer 235 on the second conductive layer 254. Each channel structure 210 can vertically extending into the stack structure 290, and can include a semiconductor pillar 215 and a gate dielectric layer 218 between the semiconductor pillar 215 and the stack structure 290 to insulating the semiconductor pillar 215 from the first conductive layer 252 and the second conductive layer 254.

Each semiconductor pillar 215 with the surrounding first conductive layer 252 and second conductive layer 254 can form two gate-all-around (GAA) type vertical transistors stacked in the vertical direction (the z-direction). In some implementations, the material of the semiconductor pillars 215 can be polysilicon. In some other implementations, a material of the semiconductor pillars 215 can be a metal oxide semiconductor material, such as indium gallium zinc oxide (IGZO). It is understood that cross section of each semiconductor pillar 215 may have any suitable shape, such as a square shape, a rectangular shape (or a trapezoidal shape), a circular shape, a partial circular shape, an oval shape, a partial oval shape, or any other suitable shapes. The bit line 260 can be connected to second ends (e.g., lower ends) of the semiconductor pillars 215.

Although not shown in FIG. 2B, first ends (e.g., upper ends) of the semiconductor pillars 215 can be connected with storage units. In some implementations, the storage unit can include any devices that can store binary data (e.g., 0 and 1), including but not limited to, capacitors for DRAM cells, and PCM elements for PCM cells. In some implementations, two stacked vertical transistors and one corresponding capacitor can form a 2T1C structure, wherein the two stacked vertical transistors can control the selection and/or the state switch of the respective capacitor coupled to the two stacked vertical transistors. It is understood that the capacitor may include any suitable structure and configuration, such as a planar capacitor, a stack capacitor, a multi-fins capacitor, a cylinder capacitor, a trench capacitor, or a substrate-plate capacitor.

The first conductive layer 252 and the second conductive layer 254 can act as the gate electrodes of the two layers of vertical transistors. The first conductive layer 252 and the second conductive layer 254 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the first conductive layer 252 and the second conductive layer 254 may include doped polysilicon, i.e., a gate poly. In some implementations, each of the first conductive layer 252 and the second conductive layer 254 can include multiple conductive layers, such as a W layer over a TiN layer.

In some implementations, the gate dielectric layer 218 is located between the semiconductor pillars 215 and the first conductive layer 252 and the second conductive layer 254. The gate dielectric layer 218 can include any suitable dielectric materials, such as silicon oxide, silicon nitride, silicon oxynitride, or high-k dielectrics. For example, the gate dielectric layer 218 may include silicon oxide, i.e., gate oxide. In some implementations, the first dielectric layer 231, the second dielectric layer 233, and the third dielectric layer 235 can include any suitable dielectric materials, such as silicon oxide, silicon nitride, silicon oxynitride, or high-k dielectrics. For example, the first dielectric layer 231, the second dielectric layer 233, and the third dielectric layer 235 may include silicon oxide.

As shown in FIGS. 2A and 2B, the disclosed memory device can further include a plurality of first isolation structures 222 and second isolation structures 224. The first isolation structures 222 can each extend along a first lateral direction (the x-direction) and vertically through the first conductive layer 252 to separate the first conductive layer 252 into first conductive lines (i.e., word lines 250 in FIG. 2A). The second isolation structures 224 can each extend along the first lateral direction (the x-direction) and vertically through the second conductive layer 254 to separate the second conductive layer 254 into second conductive lines (i.e., word lines). In some implementations, the first isolation structures 222 and the second isolation structures 224 are misaligned with each other in the vertical direction. That is, the projections of the first isolation structures 222 and the second isolation structures 224 in a lateral plane do not overlap with each other. In some implementations as shown in FIGS. 2A and 2B, each first isolation structure 222 is separated from its adjacent second isolation structures 224 by at least one row of the channel structures 210 that are aligned along the first lateral direction (the x-direction). In some implementations, the material of the first isolation structures 222 and second isolation structures 224 can be the same or different, and can include any suitable dielectric materials, such as silicon oxide, silicon nitride, silicon oxynitride, or high-k dielectrics. For example, the first isolation structures 222 and second isolation structures 224 may include silicon oxide.

As shown in FIG. 2A, the disclosed memory device can further include one or more dielectric structures 280 each vertically extending through the stack structure 290 for providing structural support of the disclosed memory device. In some implementations as shown in FIG. 2A, the dielectric structures 280 can be located between adjacent the first isolation structures 222, and each second isolation structure 224 can laterally extend through the one or more dielectric structures 280. In some other implementations not shown in the figures, the dielectric structures 280 can be located between adjacent the second isolation structures 224 and each first isolation structure 222 can laterally extend through the one or more dielectric structures 280.

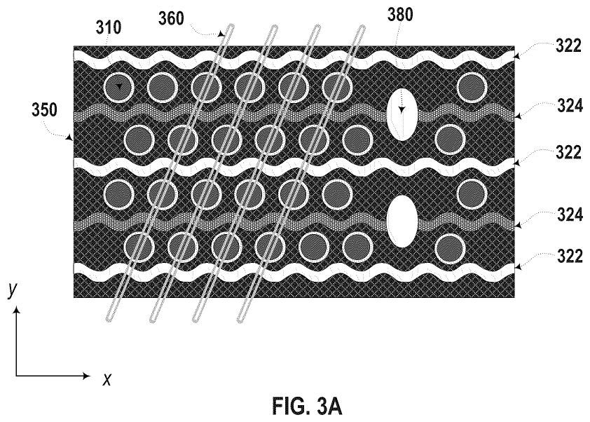

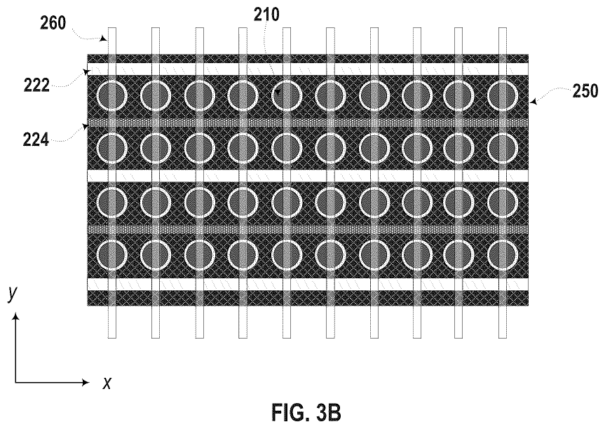

In some implementations, a cross-section of each dielectric structure 280 in a lateral plane has a round shape, an oval shape, or a short-slit shape. In some implementations, the material of the one or more dielectric structures 280 can include any suitable dielectric materials, such as silicon oxide, silicon nitride, silicon oxynitride, or high-k dielectrics. For example, the one or more dielectric structures 280 may include silicon oxide. It is noted that, the one or more dielectric structures 280 can be optional. In some implementations as shown in FIG. 3B, the disclosed memory device may not include the dielectric structures 280.

FIG. 2C illustrates a schematic plan view of the first conductive layer 252 in the memory device of FIGS. 2A and 2B, according to some implementations of the present disclosure. As shown in FIG. 2C, the first conductive layer 252 is separated by the first isolation structures 222 into word lines 262. Each two adjacent rows of channel structures 210 can share the same word line 262 as the gate structures of the formed vertical transistors. As such, the current 285 can flow along the portion of word lines 262 between adjacent rows of channel structures 210, and going around the one or more dielectric structures 280, as indicated by the arrows shown in FIG. 2C. By providing a wider path of the current flow, the risk of word line metal being cut off can be effectively eliminated.

FIG. 2D illustrates a schematic plan view of the second conductive layer 254 in the memory device of FIGS. 2A and 2B, according to some implementations of the present disclosure. As shown in FIG. 2D, the second conductive layer 254 is separated by the second isolation structures 224 into word lines 264. Each two adjacent rows of channel structures 210 can share the same word line 264 as the gate structures of the formed vertical transistors. As such, the current 295 can flow along the portion of word lines 264 between adjacent rows of channel structures 210 and between adjacent more dielectric structures 280, as indicated by the arrows shown in FIG. 2D. By providing a wider path of the current flow, the risk of word line metal being cut off can be effectively eliminated.

Referring back to FIG. 2A, the disclosed memory device further comprises a plurality of bit lines 260 each extending in a second lateral direction (the y-direction, referred to as the bit line direction) perpendicular to the first lateral direction. Each bit line 260 can be coupled with second ends (e.g., lower ends) of a corresponding column of channel structures 210. It is understood that FIG. 2A does not illustrate cross-section views of the memory device in the same lateral plane, and word lines 250 and bit lines 260 may be formed in different lateral planes for ease of routing, as described below in detail.

In some implementations, the columns of channel structures 210 in the array can be aligned along the second lateral direction (the y-direction). In such implementations, each of the first isolation structures 222 and the second isolation structures 224 can be a straight dielectric wall extending along the first direction, as shown in FIGS. 2A-2D. In some other implementations, adjacent rows of channel structures 310 can be misaligned. For example, the channel structures 310 can be aligned along a direction different from the second lateral direction (the y-direction). In such implementations, each of the first isolation structures 322 and the second isolation structures 324 can be a waved dielectric wall, as shown in FIG. 3A. Each word line 350 can have waved edges. The bit lines 360 can each extending along the direction of the slash columns of channel structures 310. One or more dielectric structures 380 each vertically extending through the first isolation structures 322 (not shown) or through the second isolation structures 324 (shown in FIG. 3A).

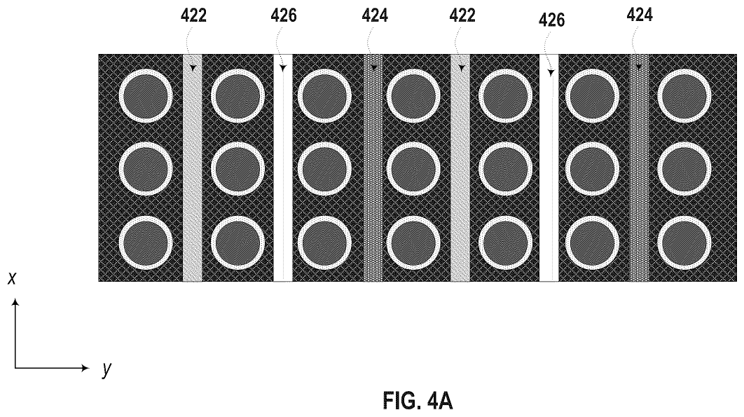

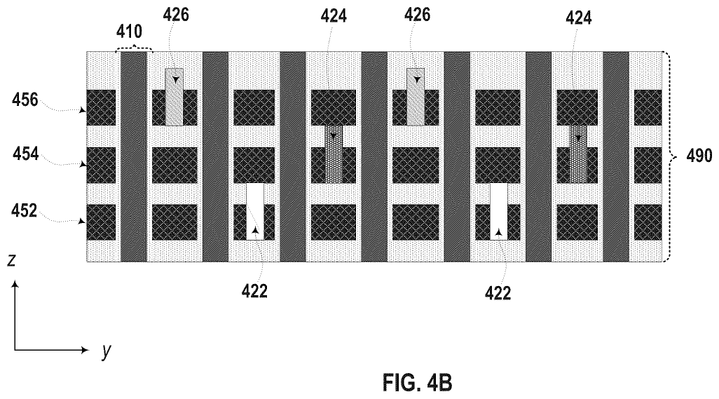

In some implementations, the stack structure of the disclosed memory device can include a number N of conductive layers to form NT1C structures. FIGS. 4A and 4B illustrating 3T1C memory device are described herein as an example. FIG. 4A illustrates a schematic plan perspective view of a memory device, according to some implementations of the present disclosure. FIG. 4B illustrates a schematic side view of a cross-section of a portion of the 3D memory device of FIG. 4A, according to some implementations of the present disclosure.

In some implementations as shown in FIGS. 4A and 4B, the stack structure 490 of the disclosed memory device can include three conductive layers 452, 454, 456. Each channel structure 410 can vertically penetrate the three conductive layers 452, 454, 456. Although not shown in FIG. 4B, the channel structures 410 can be connected with capacitors to form 3T1C structures. The disclosed memory device can further include a plurality of first isolation structures 422, second isolation structures 424, and third isolation structures 426 extending parallel along a first lateral direction (the x-direction).

The first isolation structures 422 can each extend vertically through the first conductive layer 452 to separate the first conductive layer 452 into first conductive lines (i.e., word lines). The second isolation structures 424 can each extend vertically through the second conductive layer 454 to separate the second conductive layer 454 into second conductive lines (i.e., word lines). The third isolation structures 426 can each extend vertically through the second conductive layer 454 to separate the second conductive layer 254 into second conductive lines (i.e., word lines).

In some implementations, the first isolation structures 422, the second isolation structures 424, and the third isolation structures 426 are misaligned with each other in the vertical direction. That is, the projections of the first isolation structures 422, the second isolation structures 424, and the third isolation structures 426 in a lateral plane do not overlap with each other. In some implementations as shown in FIGS. 4A and 4B, each first isolation structure 422 is separated from its adjacent second isolation structures 424 by at least one row of the channel structures 410 that are aligned along the first lateral direction (the x-direction). Each second isolation structure 424 is separated from its adjacent third isolation structures 426 by at least one row of the channel structures 410 that are aligned along the first lateral direction (the x-direction). Each third isolation structure 426 is separated from its adjacent first isolation structures 422 by at least one row of the channel structures 410 that are aligned along the first lateral direction (the x-direction).

In some implementations, the material of the first isolation structures 422, the second isolation structures 424, and the third isolation structures 426 can be the same or different, and can include any suitable dielectric materials, such as silicon oxide, silicon nitride, silicon oxynitride, or high-k dielectrics. For example, the first isolation structures 422, the second isolation structures 424, and the third isolation structures 426 may include silicon oxide.

By using the first isolation structures 422, the second isolation structures 424, and the third isolation structures 426 to separate the three conductive layers 452, 454, 456 respectively, each three adjacent rows of channel structures 410 can share a same word line in one of the three conductive layers 452, 454, 456. As such, the word line current can flow along the portion of word lines between adjacent rows of channel structures 410, to provide a wider path of the word line current flow, therefore eliminating the risk of word line metal being cut off.

In some implementations, one or more peripheral circuits (not shown) can be coupled to the disclosed memory devices shown in FIGS. 2A-2D, 3A-3B, and 4A-4B through the bit lines, the word lines, and any other suitable metal wirings. It is noted that the one or more peripheral circuits can include any suitable circuits for facilitating the operations of disclosed memory devices by applying and sensing voltage signals and/or current signals through the word lines and the bit lines to and from each memory cell. The one or more peripheral circuits can include various types of peripheral circuits formed using CMOS technologies.

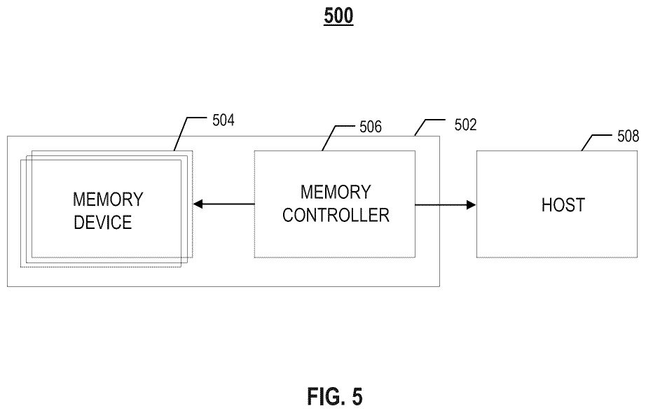

FIG. 5 illustrates a block diagram of a system 500 having a memory device, according to some implementations of the present disclosure. System 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 500 can include a host 508 and a memory system 502 having one or more memory devices 504 and a memory controller 506. Host 508 can be a processor of an electronic device, such as a central processing unit (CPU), or a system-on-chip (SoC), such as an application processor (AP). Host 508 can be configured to send or receive the data to or from memory devices 504. Memory device 504 can be any memory devices disclosed herein, such as memory devices shown in FIGS. 2A-2D, 3A-3B, and 4A-4B.

Memory controller 506 is coupled to memory device 504 and host 508 and is configured to control memory device 504, according to some implementations. Memory controller 506 can manage the data stored in memory device 504 and communicate with host 508. Memory controller 506 can be configured to control operations of memory device 504, such as read, write, and refresh operations. Memory controller 506 can also be configured to manage various functions with respect to the data stored or to be stored in memory device 504 including, but not limited to refresh and timing control, command/request translation, buffer and schedule, and power management. In some implementations, memory controller 506 is further configured to determine the maximum memory capacity that the computer system can use, the number of memory banks, memory type and speed, memory particle data depth and data width, and other important parameters. Any other suitable functions may be performed by memory controller 506 as well. Memory controller 506 can communicate with an external device (e.g., host 508) according to a particular communication protocol. For example, memory controller 506 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

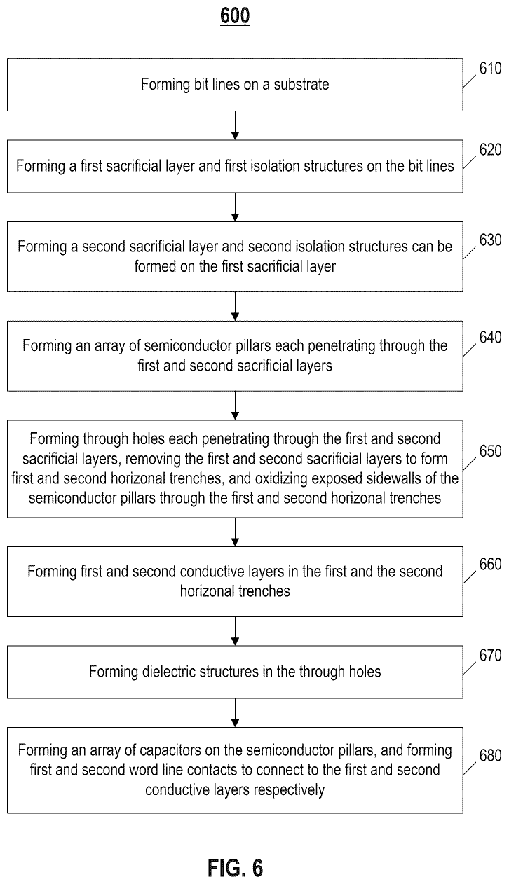

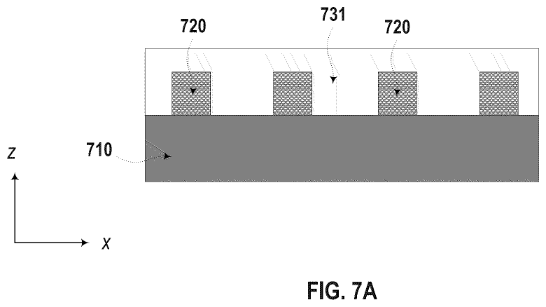

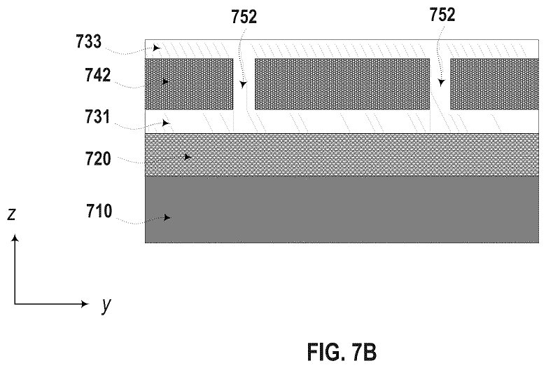

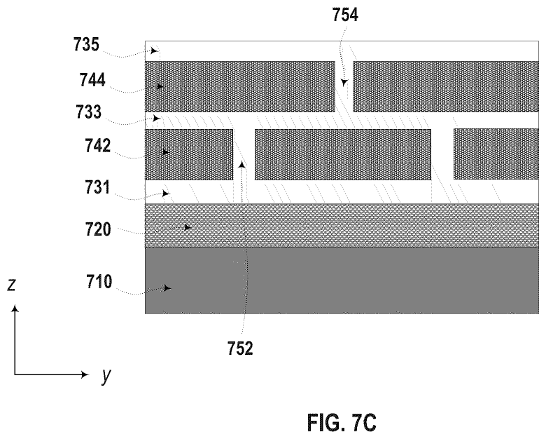

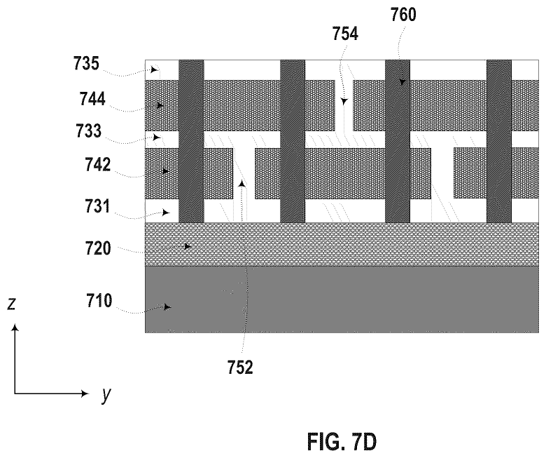

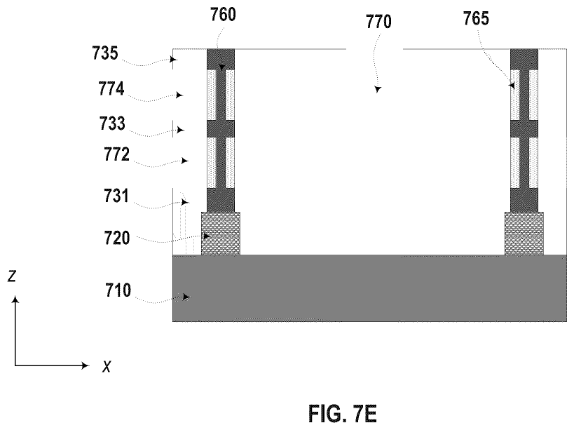

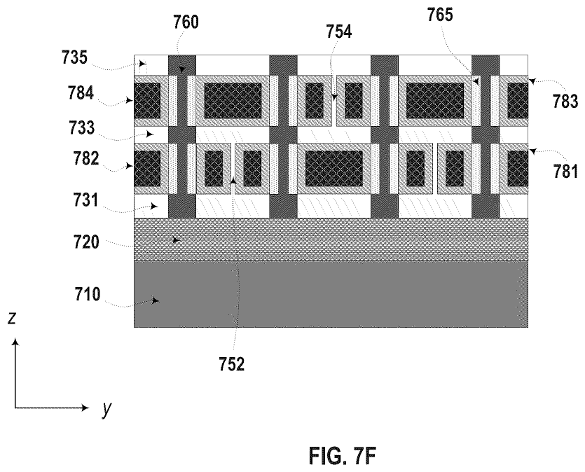

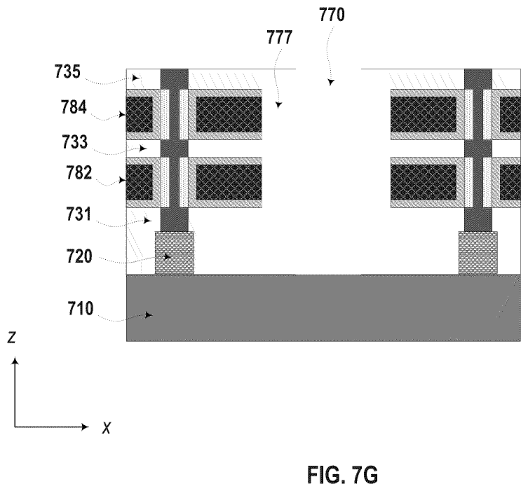

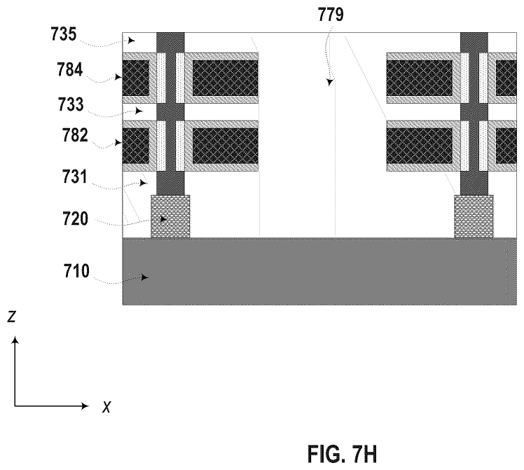

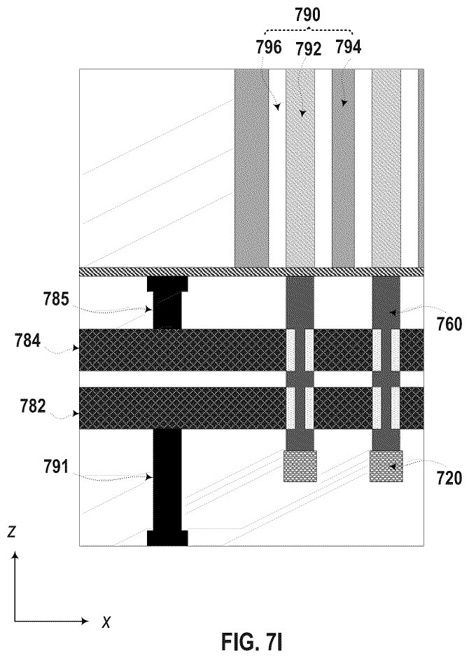

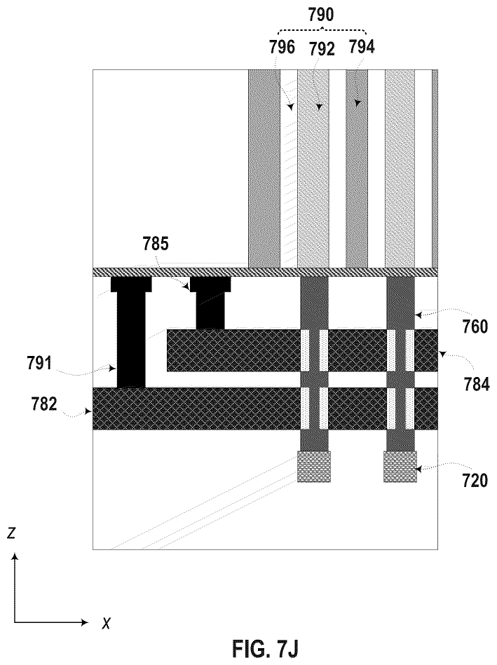

FIG. 6 illustrates a flowchart of a fabricating method 600 for forming a 3D memory device, according to some implementations of the present disclosure. FIGS. 7A-7J illustrate schematic side cross-sectional views of a 3D memory device at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 610, in which a plurality of bit lines can be formed on a substrate. FIG. 7A illustrates a schematic side cross-sectional view of the 3D memory device in the x-z plane after operation 610 of method 600.

In some implementations as shown in FIG. 7A, the substrate 710 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, the substrate 710 can be a carrier substrate, which can include any suitable semiconductor materials, or an electrically non-conductive material, such as a glass, a plastic, or a sapphire wafer.

In some implementations as shown in FIG. 7A, a conductive layer can be formed on substrate 710. The conductive layer can be patterned to form a plurality of bit lines 720, parallelly arranged in the first lateral direction (the x-direction), each extending along the second lateral direction (the y-direction). In some implementations, a lithography process can be applied to pattern the conductive layer using an etch mask (e.g., a photoresist mask and/or a hard mask), and one or more dry etching and/or wet etching processes, such as RIE, are performed on the conductive layer to etch a plurality of trenches between the bit lines 720. The bit lines 720 can include any suitable conductive materials, such as polysilicon, metals (e.g., W, Cu, Al, etc.), metal compounds (e.g., TiN, TaN, etc.), or silicides. For example, bit lines 720 include multiple conductive layers, such as a W layer over a TiN layer.

In some implementations as shown in FIG. 7A, a first dielectric layer 731 can be formed on the substrate 710 and the bit lines 720 to cover the substrate 710 and the bit lines 720 and fill spaces between the bit lines 720. The first dielectric layer 731 can be formed by a thin film deposition process, such as chemical vapor deposition (CVD), physical vapor deposition (PVD), atomic layer deposition (ALD), etc. The first dielectric layer 731 can include any suitable dielectric materials, such as silicon oxide, silicon oxynitride, or high-k dielectrics. For example, the first dielectric layer 731 may include silicon oxide.

As shown in FIG. 6, method 600 can proceed to operation 620, in which a first sacrificial layer and a plurality of first isolation structures can be formed on the bit lines. FIG. 7B illustrates a schematic side cross-sectional view of the 3D memory device in the y-z plane after operation 620 of method 600.

In some implementations as shown in FIG. 7B, a first sacrificial layer 742 can be formed on the first dielectric layer 731. The first sacrificial layer 742 can include any suitable material having an etching ratio different from that of the material of first dielectric layer 731 during one or more selective etching processes. In some implementations, the first sacrificial layer 742 includes silicon nitride, and the first dielectric layer 731 includes silicon oxide.

The first sacrificial layer 742 can be patterned to form a plurality of slits (not shown), parallelly arranged in the second lateral direction (the y-direction), each extending along the first lateral direction (the x-direction). The plurality of slits can separate the first sacrificial layer 742 into multiple blocks each extending along the first lateral direction (the x-direction).

In some implementations as shown in FIG. 7B, a plurality of first isolation structures 752 can be formed in the slits to isolate the multiple blocks of the first sacrificial layer 742. A second dielectric layer 733 can be formed on the first sacrificial layer 742. The first isolation structures 752 and the second dielectric layer 733 can include any suitable dielectric materials, such as silicon oxide, silicon oxynitride, or high-k dielectrics. In some implementations, when the first isolation structures 752 and the second dielectric layer 733 have a same dielectric material, such as silicon oxide, the first isolation structures 752 and the second dielectric layer 733 can be formed by a same deposition process by depositing the same dielectric material over the first sacrificial layer 742 to fill the slits between the blocks and cover the first sacrificial layer 742. In some other implementations, when the first isolation structures 752 and the second dielectric layer 733 have different dielectric materials, a first deposition process of a first dielectric material and a followed chemical mechanical polishing (CMP) process can be used to form the first isolation structures 752, and a second deposition process of a second dielectric material can be used to form the second dielectric layer 733.

As shown in FIG. 6, method 600 can proceed to operation 630, in which a second sacrificial layer and a plurality of second isolation structures can be formed on the first sacrificial layer. FIG. 7C illustrates a schematic side cross-sectional view of the 3D memory device in y-z plane after operation 630 of method 600.

In some implementations as shown in FIG. 7C, a second sacrificial layer 744 can be formed on the second dielectric layer 733. The second sacrificial layer 744 can include any suitable material having an etching ratio different from that of the material of second dielectric layer 733 during one or more selective etching processes. In some implementations, the second sacrificial layer 744 includes silicon nitride, and the second dielectric layer 733 includes silicon oxide.

The second sacrificial layer 744 can be patterned to form a plurality of slits (not shown), parallelly arranged in the second lateral direction (the y-direction), each extending along the first lateral direction (the x-direction). The plurality of slits can separate the second sacrificial layer 744 into multiple blocks each extending along the first lateral direction (the x-direction).

In some implementations as shown in FIG. 7C, a plurality of second isolation structures 754 can be formed in the slits to isolate the multiple blocks of the second sacrificial layer 744. In some implementations, the first isolation structures 752 and the second isolation structures 754 are misaligned with each other in the vertical direction. That is, the projections of the first isolation structures 752 and the second isolation structures 754 in a lateral plane do not overlap with each other.

A third dielectric layer 735 can be formed on the second sacrificial layer 744. The second isolation structures 754 and the third dielectric layer 735 can include any suitable dielectric materials, such as silicon oxide, silicon oxynitride, or high-k dielectrics. In some implementations, when the second isolation structures 754 and the third dielectric layer 735 have a same dielectric material, such as silicon oxide, the second isolation structures 754 and the third dielectric layer 735 can be formed by a same deposition process by depositing the same dielectric material over the second sacrificial layer 744 to fill the slits between the blocks and cover the second sacrificial layer 744. In some other implementations, when the second isolation structures 754 and the third dielectric layer 735 have different dielectric materials, a first deposition process of a first dielectric material and a followed chemical mechanical polishing (CMP) process can be used to form the second isolation structures 754, and a second deposition process of a second dielectric material can be used to form the third dielectric layer 735.

As shown in FIG. 6, method 600 can proceed to operation 640, in which an array of semiconductor pillars can be formed to penetrate through the first and second sacrificial layers. FIG. 7D illustrates a schematic side cross-sectional view of the 3D memory device in the y-z plane after operation 640 of method 600.

In some implementations, an array of channel holes (not shown) can be formed, each penetrating through the first and second sacrificial layers 742, 744, and the first, second, third dielectric layers 731, 733, 735 to expose a corresponding one of the plurality of bit lines 720. The array of channel holes can be formed by using any suitable etching processes. As shown in FIG. 7D, an array of semiconductor pillars 760 can be formed in the plurality of channel holes, respectively. Lower ends of the semiconductor pillars 760 can be coupled with the corresponding bit lines 720. In some implementations, each row of the array of semiconductor pillars 760 aligned along the first lateral direction (the x-direction) can be located between an adjacent pair of first isolation structure 752 and second isolation structure 754.

The array of semiconductor pillars 760 can be formed by any suitable deposition process (e.g., CVD, PVD, ALD, etc.) and a followed CMP process. In some implementations, a material of the semiconductor pillars 760 can include any suitable semiconductor material. For example, the material of the semiconductor pillars 760 can be polysilicon. As another example, a material of the semiconductor pillars 760 can be a metal oxide semiconductor material, such as IGZO. It is understood that cross section of each semiconductor pillar 760 may have any suitable shape, such as a square shape, a rectangular shape (or a trapezoidal shape), a circular shape, a partial circular shape, an oval shape, a partial oval shape, or any other suitable shapes.

As shown in FIG. 6, method 600 can proceed to operation 650, in which a plurality of through holes can be formed to penetrate through the first and second sacrificial layers, the first and second sacrificial layers can be removed to form first horizontal trenches and second horizontal trenches that expose sidewalls of the semiconductor pillars, and the exposed sidewalls of the semiconductor pillars can be oxidized to form gate dielectric layers. FIG. 7E illustrates a schematic side cross-sectional view of the 3D memory device in the x-z plane after operation 650 of method 600.

In some implementations as shown in FIG. 7E, a plurality of through holes 770 can be formed, each penetrating through the first and second sacrificial layers 742, 744, and the first, second, third dielectric layers 731, 733, 735 to expose the substrate 710. The plurality of through holes 770 can be formed by using any suitable etching processes. As shown in FIG. 7E, the first and second sacrificial layers 742, 744 can be removed from the through holes 770 to form first horizontal trenches 772 and second horizontal trenches 774. The first horizontal trenches 772 and second horizontal trenches 774 can expose portions of the sidewalls of the semiconductor pillars 760. The first and second sacrificial layers 742, 744 can be removed by using any suitable etching processes. The exposed portions of the sidewalls of semiconductor pillars 760 can be oxidized to form oxide layers, which are used as gate dielectric layers 765.

As shown in FIG. 6, method 600 can proceed to operation 660, in which first and second conductive layers can be formed in the first horizontal trenches and the second horizontal trenches. FIG. 7F illustrates a schematic side cross-sectional view of the 3D memory device in y-z plane after operation 660 of method 600.

In some implementations as shown in FIG. 7F, insulating layers 781, 783 can be formed to cover the exposed surfaces of the first horizontal trenches 772 and the second horizontal trenches 774. The insulating layers 781, 783 can include any suitable dielectric materials, such as silicon oxide, silicon nitride, silicon oxynitride, or high-k dielectrics. One or more conductive materials can be deposited on the insulating layers 781, 783 to fill the first horizontal trenches 772 and the second horizontal trenches 774. The formed first conductive layer 782 and second conductive layer 784 can be used as the gate electrodes of the vertical transistors, and can include any suitable conductive materials, such as polysilicon, metals (e.g., W, Cu, Al, etc.), metal compounds (e.g., TiN, TaN, etc.), or silicides. For example, the first conductive layer 782 and the second conductive layer 784 may include doped polysilicon, i.e., a gate poly. In some implementations, the first conductive layer 782 and the second conductive layer 784 can include multiple conductive layers, such as a W layer over a TiN layer.

The formed first conductive layer 782 can be separated by the first isolation structure 752 to form first gate electrodes for the lower array of vertical transistors. The first gate electrodes of each row of the lower array of vertical transistors are connected with each other and extend along the first lateral direction (the x-direction) to form one first word line. Similarly, the second conductive layer 784 can be separated by the second isolation structures 754 to form second gate electrodes for the upper array of vertical transistors. The second gate electrodes of each row of the upper array of vertical transistors are connected with each other and extend along the first lateral direction (the x-direction) to form one second word line.

As shown in FIG. 6, method 600 can proceed to operation 670, in which dielectric structures can be formed in the through holes. FIG. 7G illustrates a schematic side cross-sectional view of the 3D memory device in the x-z plane during operation 670 of method 600. FIG. 7H illustrates a schematic side cross-sectional view of the 3D memory device in the x-z plane after operation 670 of method 600.

In some implementations as shown in FIG. 7G, an etch back process can be performed to remove portions of the insulating layers 781, 783 and/or first conductive layer 782 and second conductive layer 784 within or close to the through holes 770. As such, a plurality of recesses 777 can be formed. In some implementations as shown in FIG. 7G, a dielectric material can be deposited to fill the recesses 777 and the through holes 770 to form dielectric structures 779. The dielectric structures 779 can provide support for the formed 3D memory device. The dielectric structures 779 can include any suitable dielectric materials, such as silicon oxide, silicon oxynitride, or high-k dielectrics. For example, the dielectric structures 779 may include silicon oxide.

As shown in FIG. 6, method 600 can proceed to operation 680, in which an array of capacitors can be formed on the semiconductor pillars, and first and second word line contacts can be formed to connect to the first and second conductive layers, respectively. FIG. 7I illustrates a schematic side cross-sectional view of the 3D memory device in x-z plane after operation 680 of method 600, in some implementation of the present disclosure. FIG. 7J illustrates a schematic side cross-sectional view of the 3D memory device in x-z plane after operation 680 of method 600, in some other implementation of the present disclosure.

As shown in FIGS. 71 and 7J, an array of capacitors 790 can be formed on the semiconductor pillars 760. The array of capacitors 790 can include a common second electrode 794, a plurality of first electrode 792, and a capacitor dielectric layer 796 between the first electrodes 792 and the common second electrode 794. In some implementations, the first electrodes 792 and/or the common second electrode 794 can include conductive materials including, but not limited to, W, Co, Cu, Al, TiN, TaN, polysilicon, silicides, or any combination thereof. In some implementations, the capacitor dielectric layer 796 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors 790 can be formed by a series of fabricating processes including thin film deposition processes (e.g., CVD, PVD, ALD, etc.) and patterning processes (e.g., photoetching, dry etching, wet etching, cleaning, CMP, etc.). It is noted that, the fabricating processes and/or orders of forming the first electrodes 792, the common second electrode 794, and the capacitor dielectric layer 796 can be varied depending on a front side process or a back side process.

As shown in FIGS. 7I and 7J, first word line contacts 791 can be formed to connect to the first conductive layer 782, and second word line contacts 785 can be formed to connect to the second conductive layer 784. The first word line contacts 791 and the second word line contacts 785 can include any suitable conductive materials, such as polysilicon, metals (e.g., W, Cu, Al, etc.), metal compounds (e.g., TiN, TaN, etc.), or silicides. In some implementations, the first word line contacts 791 and the second word line contacts 785 can be formed by a series of fabricating processes including thin film deposition processes (e.g., CVD, PVD, ALD, etc.) and patterning processes (e.g., photoetching, dry etching, wet etching, cleaning, CMP, etc.).

In some implementations as shown in FIG. 7I, the first word line contacts 791 and the second word line contacts 785 can be formed on different sides of the first conductive layer 782 and the second conductive layer 784. That is, the first word line contacts 791 can be formed to be in contact with a lower surface of the first conductive layer 782, and the second word line contacts 785 can be formed to be in contact with an upper surface of the second conductive layer 784. In some other implementations as shown in FIG. 7J, the first word line contacts 791 and the second word line contacts 785 can be formed on a same side of the first conductive layer 782 and the second conductive layer 784. That is, the edges of the first conductive layer 782 and the second conductive layer 784 can form a stair structures, and the first word line contacts 791 and the second word line contacts 785 can both be formed on upper surfaces of the first conductive layer 782 and the second conductive layer 784 respectively.

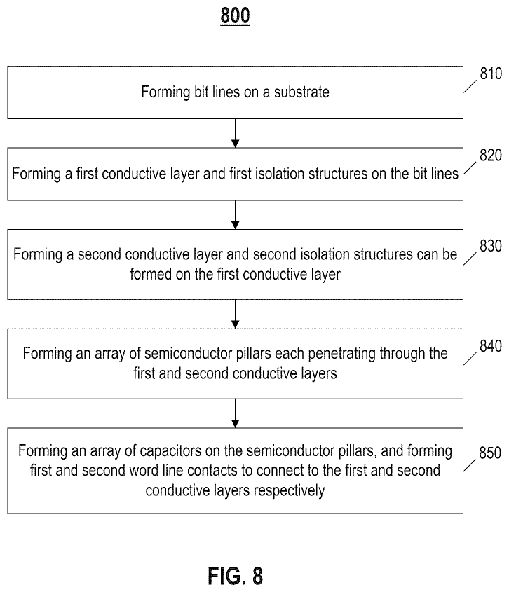

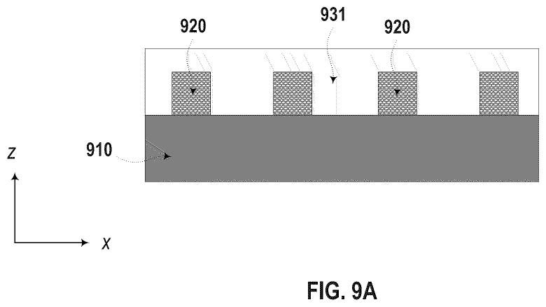

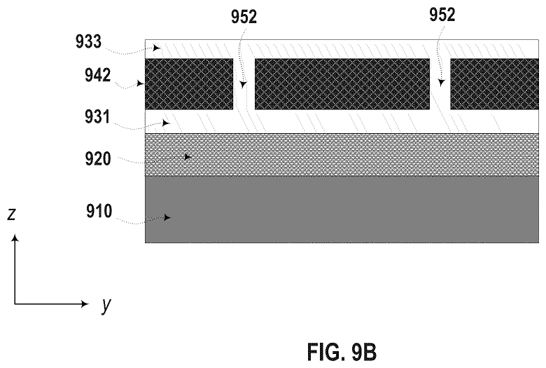

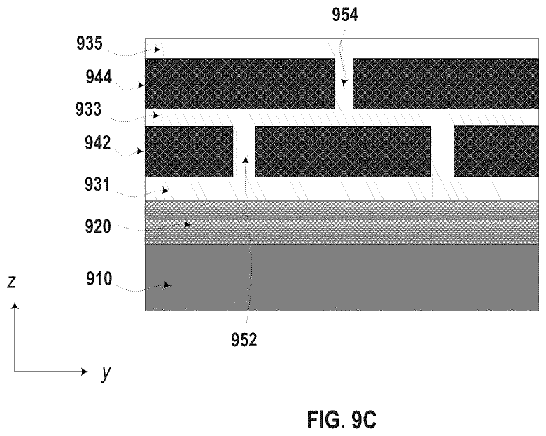

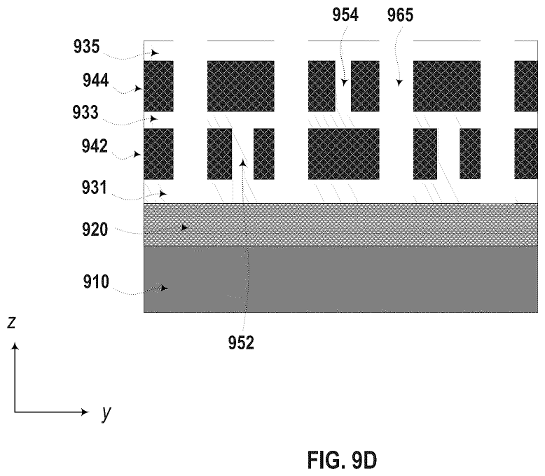

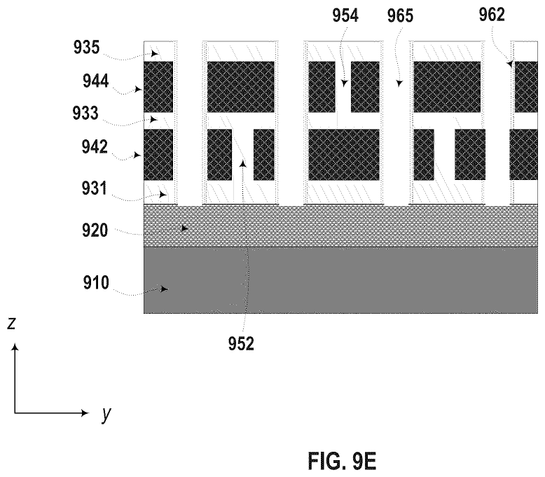

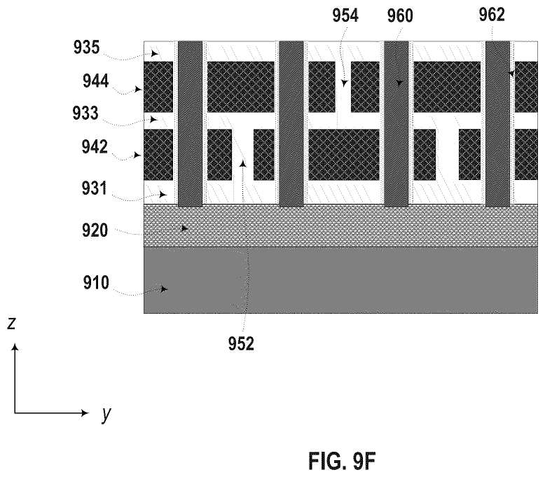

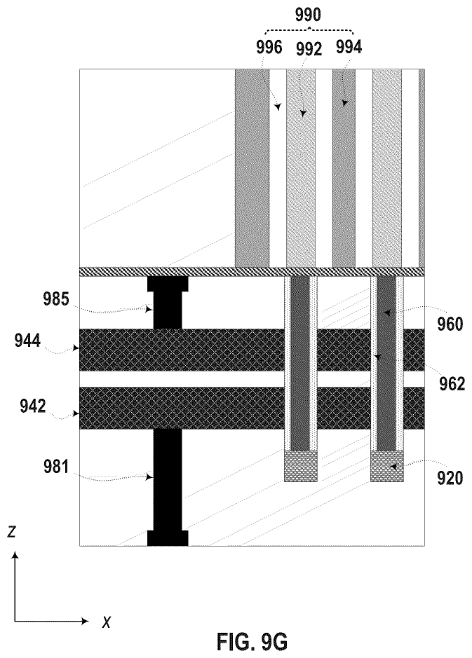

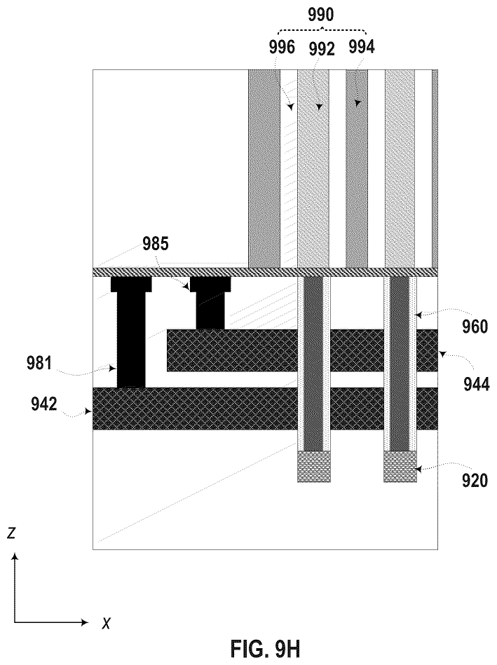

FIG. 8 illustrates a flowchart of a fabricating method 800 for forming a 3D memory device, according to some implementations of the present disclosure. FIGS. 9A-9H illustrate schematic side cross-sectional views of a 3D memory device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 can start at operation 810, in which a plurality of bit lines can be formed on the array of capacitors. FIG. 9A illustrates a schematic side cross-sectional view of the 3D memory device in the x-z plane after operation 810 of method 800.

In some implementations as shown in FIG. 9A, the substrate 910 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, the substrate 910 can be a carrier substrate, which can include any suitable semiconductor materials, or an electrically non-conductive material, such as a glass, a plastic, or a sapphire wafer.

In some implementations as shown in FIG. 9A, a conductive layer can be formed on substrate 910. The conductive layer can be patterned to form a plurality of bit lines 920, parallelly arranged in the first lateral direction (the x-direction), each extending along the second lateral direction (the y-direction). In some implementations, a lithography process can be applied to pattern the conductive layer using an etch mask (e.g., a photoresist mask and/or a hard mask), and one or more dry etching and/or wet etching processes, such as RIE, are performed on the conductive layer to etch a plurality of trenches between the bit lines 920. The bit lines 920 can include any suitable conductive materials, such as polysilicon, metals (e.g., W, Cu, Al, etc.), metal compounds (e.g., TiN, TaN, etc.), or silicides. For example, bit lines 920 includes multiple conductive layers, such as a W layer over a TiN layer.

In some implementations as shown in FIG. 9A, a first dielectric layer 931 can be formed on the substrate 910 and the bit lines 920 to cover the substrate 910 and the bit lines 920 and fill spaces between the bit lines 920. The first dielectric layer 931 can be formed by a thin film deposition process, such as chemical vapor deposition (CVD), physical vapor deposition (PVD), atomic layer deposition (ALD), etc. The first dielectric layer 931 can include any suitable dielectric materials, such as silicon oxide, silicon oxynitride, or high-k dielectrics. For example, the first dielectric layer 931 may include silicon oxide.

As shown in FIG. 8, method 800 can proceed to operation 820, in which a first conductive layer and a plurality of first isolation structures can be formed on the bit lines. FIG. 9B illustrates a schematic side cross-sectional view of the 3D memory device in the y-z plane after operation 820 of method 800.

In some implementations as shown in FIG. 9B, a first conductive layer 942 can be formed on the first dielectric layer 931. The first conductive layer 942 can include any suitable conductive materials, such as polysilicon, metals (e.g., W, Cu, Al, etc.), metal compounds (e.g., TiN, TaN, etc.), or silicides. In some implementations, the first conductive layer 942 can include multiple conductive layers, such as a W layer over a TiN layer. The first conductive layer 942 can be patterned to form a plurality of slits (not shown), parallelly arranged in the second lateral direction (the y-direction), each extending along the first lateral direction (the x-direction). The plurality of slits can separate the first conductive layer 942 into multiple blocks each extending along the first lateral direction (the x-direction).

In some implementations as shown in FIG. 9B, a plurality of first isolation structures 952 can be formed in the slits to isolate the multiple blocks of the first conductive layer 942. The first conductive layer 942 can be separated by the first isolations structure 952 to form first gate electrodes for the lower array of vertical transistors. The first gate electrodes of each row of the lower array of vertical transistors are connected with each other and extend along the first lateral direction (the x-direction) to form one first word line.

A second dielectric layer 933 can be formed on the first conductive layer 942. The first isolation structures 952 and the second dielectric layer 933 can include any suitable dielectric materials, such as silicon oxide, silicon oxynitride, or high-k dielectrics. In some implementations, when the first isolation structures 952 and the second dielectric layer 933 have a same dielectric material, such as silicon oxide, the first isolation structures 952 and the second dielectric layer 933 can be formed by a same deposition process by depositing the same dielectric material over the first conductive layer 942 to fill the slits between the blocks and cover the first conductive layer 942. In some other implementations, when the first isolation structures 952 and the second dielectric layer 933 have different dielectric materials, a first deposition process of a first dielectric material and a followed chemical mechanical polishing (CMP) process can be used to form the first isolation structures 952, and a second deposition process of a second dielectric material can be used to form the second dielectric layer 933.

As shown in FIG. 8, method 800 can proceed to operation 830, in which a second conductive layer and second isolation structures can be formed on the first conductive layer. FIG. 9C illustrates a schematic side cross-sectional view of the 3D memory device in the y-z plane after operation 830 of method 800.

In some implementations as shown in FIG. 9C, a second conductive layer 944 can be formed on the second dielectric layer 933. The second conductive layer 944 can include any suitable conductive materials, such as polysilicon, metals (e.g., W, Cu, Al, etc.), metal compounds (e.g., TiN, TaN, etc.), or silicides. In some implementations, the second conductive layer 944 can include multiple conductive layers, such as a W layer over a TiN layer. The second conductive layer 944 can be patterned to form a plurality of slits (not shown), parallelly arranged in the second lateral direction (the y-direction), each extending along the first lateral direction (the x-direction). The plurality of slits can separate the second conductive layer 944 into multiple blocks each extending along the first lateral direction (the x-direction).

In some implementations as shown in FIG. 9C, a plurality of second isolation structures 954 can be formed in the slits to isolate the multiple blocks of the second conductive layer 944. In some implementations, the first isolation structures 952 and the second isolation structures 954 are misaligned with each other in the vertical direction. That is, the projections of the first isolation structures 952 and the second isolation structures 954 in a lateral plane do not overlap with each other. The second conductive layer 944 can be separated by the second isolation structures 954 to form second gate electrodes for the upper array of vertical transistors. The second gate electrodes of each row of the upper array of vertical transistors are connected with each other and extend along the first lateral direction (the x-direction) to form one second word line.

A third dielectric layer 935 can be formed on the second conductive layer 944. The second isolation structures 954 and the third dielectric layer 935 can include any suitable dielectric materials, such as silicon oxide, silicon oxynitride, or high-k dielectrics. In some implementations, when the second isolation structures 954 and the third dielectric layer 935 have a same dielectric material, such as silicon oxide, the second isolation structures 954 and the third dielectric layer 935 can be formed by a same deposition process by depositing the same dielectric material over the second conductive layer 944 to fill the slits between the blocks and cover the second conductive layer 944. In some other implementations, when the second isolation structures 954 and the third dielectric layer 935 have different dielectric materials, a first deposition process of a first dielectric material and a followed chemical mechanical polishing (CMP) process can be used to form the second isolation structures 954, and a second deposition process of a second dielectric material can be used to form the third dielectric layer 935.

As shown in FIG. 8, method 800 can proceed to operation 840, in which an array of semiconductor pillars can be formed to penetrate through the first and second conductive layers. FIG. 9D illustrates a schematic side cross-sectional view of the 3D memory device in the y-z plane during operation 840 of method 800. FIG. 9E illustrates a schematic side cross-sectional view of the 3D memory device in the y-z plane during operation 840 of method 800. FIG. 9F illustrates a schematic side cross-sectional view of the 3D memory device in the y-z plane after operation 840 of method 800.

In some implementations as shown in FIG. 9D, an array of channel holes 965 can be formed, each penetrating through the first and second conductive layers 942, 944, and the first, second, third dielectric layers 931, 933, 935 to expose a corresponding one of the plurality of bit lines 920. The array of channel holes 965 can be formed by using any suitable etching processes. In some implementations, each row of the array of channel holes 965 aligned along the first lateral direction (the x-direction) can be located between an adjacent pair of first isolation structure 952 and second isolation structure 954. In some implementations as shown in FIG. 9E, a dielectric layer 962 can be formed on sidewalls of the channel holes 965. The dielectric layer 962 can include any suitable dielectric materials, such as silicon oxide, silicon nitride, silicon oxynitride, or high-k dielectrics, and can be used as a gate dielectric layer.

In some implementations as shown in FIG. 9F, an array of semiconductor pillars 960 can be formed in the plurality of channel holes 965, respectively. Lower ends of the semiconductor pillars 960 can be coupled with the corresponding bit lines 920. In some implementations, each row of the array of semiconductor pillars 960 aligned along the first lateral direction (the x-direction) can be located between an adjacent pair of first isolation structure 952 and second isolation structure 954.

The array of semiconductor pillars 960 can be formed by any suitable deposition process (e.g., CVD, PVD, ALD, etc.) and a followed CMP process. In some implementations, a material of the semiconductor pillars 960 can include any suitable semiconductor material. For example, the material of the semiconductor pillars 960 can be polysilicon. As another example, a material of the semiconductor pillars 960 can be a metal oxide semiconductor material, such as IGZO. It is understood that cross section of each semiconductor pillar 960 may have any suitable shape, such as a square shape, a rectangular shape (or a trapezoidal shape), a circular shape, a partial circular shape, an oval shape, a partial oval shape, or any other suitable shapes.

As shown in FIG. 8, method 800 can proceed to operation 850, in which an array of capacitors can be formed on the semiconductor pillars, and first and second word line contacts can be formed to connect to the first and second conductive layers, respectively. FIG. 9G illustrates a schematic side cross-sectional view of the 3D memory device in the y-z plane after operation 850 of method 800, in some implementation of the present disclosure. FIG. 9H illustrates a schematic side cross-sectional view of the 3D memory device in the y-z plane after operation 850 of method 800, in some other implementation of the present disclosure.

As shown in FIGS. 9G and 9H, an array of capacitors 990 can be formed on the semiconductor pillars 960. The array of capacitors 990 can include a common second electrode 994, a plurality of first electrode 992, and a capacitor dielectric layer 996 between the first electrodes 992 and the common second electrode 994. In some implementations, the first electrodes 992 and/or the common second electrode 994 can include conductive materials including, but not limited to, W, Co, Cu, Al, TiN, TaN, polysilicon, silicides, or any combination thereof. In some implementations, the capacitor dielectric layer 996 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the array of capacitors 990 can be formed by a series of fabricating processes including thin film deposition processes (e.g., CVD, PVD, ALD, etc.) and patterning processes (e.g., photoetching, dry etching, wet etching, cleaning, CMP, etc.). It is noted that, the fabricating processes and/or orders of forming the first electrodes 992, the common second electrode 994, and the capacitor dielectric layer 996 can be varied depending on a front side process or a back side process.

As shown in FIGS. 9G and 9H, first word line contacts 981 can be formed to connect to the first conductive layer 942, and second word line contacts 985 can be formed to connect to the second conductive layer 944. The first word line contacts 981 and the second word line contacts 985 can include any suitable conductive materials, such as polysilicon, metals (e.g., W, Cu, Al, etc.), metal compounds (e.g., TiN, TaN, etc.), or silicides. In some implementations, the first word line contacts 981 and the second word line contacts 985 can be formed by a series of fabricating processes including thin film deposition processes (e.g., CVD, PVD, ALD, etc.) and patterning processes (e.g., lithography, dry etching, wet etching, cleaning, CMP, etc.).

In some implementations as shown in FIG. 9G, the first word line contacts 981 and the second word line contacts 985 can be formed on different sides of the first conductive layer 942 and the second conductive layer 944. That is, the first word line contacts 981 can be formed to be in contact with a lower surface of the first conductive layer 942, and the second word line contacts 985 can be formed to be in contact with an upper surface of the second conductive layer 944. In some other implementations as shown in FIG. 9H, the first word line contacts 981 and the second word line contacts 985 can be formed on a same side as the first conductive layer 942 and the second conductive layer 944. That is, the edges of the first conductive layer 942 and the second conductive layer 944 can form a stair structures, and the first word line contacts 981 and the second word line contacts 985 can both be formed on the upper surfaces of the first conductive layer 942 and the second conductive layer 944 respectively.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A semiconductor device, comprising:
an array of channel structures each vertically extending in a stack structure comprising a first conductive layer and a second conductive layer over the first conductive layer;
first isolation structures each extending along a first lateral direction and separating the first conductive layer into first conductive lines; and
second isolation structures each extending along the first lateral direction and separating the second conductive layer into second conductive lines,
wherein each first isolation structure is separated from the second isolation structures by at least one row of the channel structures that are aligned along the first lateral direction.

2. The semiconductor device of claim 1, wherein:
one of the first conductive lines laterally extending along the first lateral direction and surrounds each channel structure in a first row of the array and a second row of the array adjacent to the first row; and
one of the second conductive lines laterally extending along the first lateral direction and surrounds each channel structure in the second row of the array and a third row of the array adjacent to the second row.

3. The semiconductor device of claim 1, wherein:
the stack structure further comprises a third conductive layer on the third conductive layer;
the semiconductor device further comprises third isolation structures each extending along the first lateral direction and separating the third conductive layer into third conductive lines; and
each third isolation structure is separated from the first isolation structures and the second isolation structures by at least one row of the channel structures.

4. The semiconductor device of claim 3, further comprising:
one of the first conductive lines laterally extending along the first lateral direction and surrounds each channel structure in a first row of the array, a second row of the array adjacent to the first row, and a third row of the array adjacent to the second row;
one of the second conductive lines laterally extending along the first lateral direction and surrounds each channel structure in the second row and the third row of the array, and a fourth row of the array adjacent to the third row; and
one of the third conductive lines laterally extending along the first lateral direction and surrounds each channel structure in the third row and the fourth row of the array, and a fifth row of the array adjacent to the fourth row.

5. The semiconductor device of claim 1, further comprising:
dielectric structures each vertically extending through the stack structure and one first isolation structure or second isolation structure.

6. The semiconductor device of claim 5, further comprising:
a cross-section of each dielectric structure in a lateral plane has a round shape, an oval shape, or a short-slit shape.

7. The semiconductor device of claim 1, wherein:
each of the first isolation structures and the second isolation structures includes a straight dielectric wall.

8. The semiconductor device of claim 7, further comprising:
bit lines each connected with a corresponding column of channel structures and laterally extending along a second lateral direction perpendicular to the first lateral direction.

9. The semiconductor device of claim 1, wherein:
each of the first isolation structures and the second isolation structures has a waved dielectric wall.

10. The semiconductor device of claim 9, further comprising:
bit lines connected with the channel structures and laterally extending parallel along a second lateral direction non-perpendicular to the first lateral direction.

11. The semiconductor device of claim 1, further comprising:
first word line contacts connected with the first conductive lines, respectively; and
second word line contacts connected with the second conductive lines, respectively,
wherein the first word line contacts and the second word line contacts are located on a same side as the first conductive layer and the second conductive layer.

12. The semiconductor device of claim 1, further comprising:
first word line contacts connected with a first side of the first conductive lines, respectively; and
second word line contacts connected with a second side of the second conductive lines, respectively,
wherein the first side and the second side are opposite to each other.

13. The semiconductor device of claim 1, wherein each channel structure comprises:
a semiconductor core vertically extending in the stack structure; and
a gate dielectric layer laterally surrounding the semiconductor core and vertically extending in the stack structure.

14. The semiconductor device of claim 1, wherein each channel structure comprises:
a semiconductor core vertically extending in the stack structure;
a first gate dielectric layer laterally surrounding a first portion of the semiconductor core corresponding to the first conductive layer; and
a second gate dielectric layer laterally surrounding a second portion of the semiconductor core corresponding to the second conductive layer,
wherein the first gate dielectric layer is separated from the second gate dielectric layer by a third portion of the semiconductor core between the first portion and the second portion.

15. The semiconductor device of claim 14, wherein:
a first lateral size of the first portion of the semiconductor core is substantially equal to a second lateral size of the second portion of the semiconductor core; and
a third lateral size of the third portion of the semiconductor core is substantially equal to the first lateral size of the first portion of the semiconductor core plus a lateral thickness of the first gate dielectric layer.

16. The semiconductor device of claim 1, further comprising:
an array of capacitors, each capacitor connected with a corresponding channel structure.

17. The semiconductor device of claim 6, wherein:
a cross-section of each channel structure in the lateral plane is a round shape or an oval shape.

18. The semiconductor device of claim 1, wherein:
the first isolation structures each extending through the first conductive layer and without extending through the second conductive layer; and
the second isolation structures each extending through the second conductive layer and without extending through the first conductive layer.

19. A memory device, comprising:
an array of channel structures each vertically extending in a stack structure comprising a first conductive layer and a second conductive layer over the first conductive layer;
first isolation structures each extending along a first lateral direction and separating the first conductive layer into first conductive lines;
second isolation structures each extending along the first lateral direction and separating the second conductive layer into second conductive lines, wherein each first isolation structure is separated from the second isolation structures by at least one row of the channel structures that are aligned along the first lateral direction;
first word line contacts connected with the first conductive lines, respectively;
second word line contacts connected with the second conductive lines, respectively; and
bit lines each connected with a corresponding column of channel structures and laterally extending along a second lateral direction different from the first lateral direction.

20. A memory system, comprising:
a memory device, comprising:
an array of channel structures each vertically extending in a stack structure comprising a first conductive layer and a second conductive layer over the first conductive layer,
first isolation structures each extending along a first lateral direction and separating the first conductive layer into first conductive lines,
second isolation structures each extending along the first lateral direction and separating the second conductive layer into second conductive lines, wherein each first isolation structure is separated from the second isolation structures by at least one row of the channel structures that are aligned along the first lateral direction,
first word line contacts connected with the first conductive lines, respectively,
second word line contacts connected with the second conductive lines, respectively, and
bit lines each connected with a corresponding column of channel structures and laterally extending along a second lateral direction different from the first lateral direction; and
a memory controller coupled with the memory device and configured to control the memory device.
